(19) United States
(12) Patent Application Publication
(10) Pub. No.: US 2016/0339603 A1
(43) Pub. Date: Nov. 24, 2016

(54) METHOD FOR SPLITTING CIRCLES

(71) Applicant: YOUNGTEK ELECTRONICS CORPORATION, Hsinchu City (TW)

(72) Inventors: WEN-MING LIU, Hsinchu City (TW); JUI-HUAI CHENG, Hsinchu City (TW); CHAO-CHING WU, Hsinchu City (TW); CHING-TSUNG CHANG, Hsinchu City (TW)

(21) Appl. No.: 14/803,098

(22) Filed: Jul. 19, 2015

(30) Foreign Application Priority Data
May 22, 2015 (TW) 104116400

(51) Int. Cl. B28D 5/00; H01L 21/304; H01L 21/78

(52) U.S. Cl. CPC B28D 5/0005; H01L 21/78; H01L 21/304

(57) ABSTRACT

The present invention relates to a method for splitting circles, and the method is mainly applied to a wafer of semiconductors. A plurality of splitting blades are disposed above the wafer, and conditions and steps are set for switching the plurality of splitting blades based on a safe distance value set at an outer edge of a wafer or a safe distance value set at an inner edge of a metal ring. Accordingly, the plurality of splitting blades are prevented from cutting an outer frame during splitting and failing to complete actions of splitting wafers. The method has an advantage of efficiency of enhancing a production capacity yield rate.

### BACKGROUND OF THE INVENTION

1. Field of the Invention

The present invention relates to a method for splitting circles, and especially to a method of switching splitting blades by setting conditions/steps so as to acquire efficiency of enhancing a production capacity yield rate. The method is applicable to wafer splitting processes or similar processes.

2. The Related Arts

Presently, in the semiconductor industry, a wafer made after manufacturing is required to be proceeded with a splitting process in order to be cut into dies one by one for being convenient for further proceeding with packaging.

However, in existing splitting processes adopted by the current industry, wafers are loaded in a carrier circular tray having a larger size. For example, a 12-inch wafer will be carried by a 16-inch carrier circular tray to prevent a cutting blade from cutting an outer frame of the carrier circular tray during splitting and to further cause the cutting blade being damaged or the cutting blade failing to completely split the wafers and leading to results of raising working hours and incapacity of enhancing productivity yield rates of wafers.

In addition, due to trends of enlarging wafer sizes, larger carrier circular trays are required to be prepared. Preparation of larger carrier circular trays is not much economic.

In view of the above drawbacks, the named inventor(s) of the present invention makes painstaking efforts to research and study, design and fabricate, and expects to provide a method for splitting circles which is able to adjust splitting blade conditions in order to provide users with convenient operations/assembly. The above is inventive motives of the named inventors of the present invention to research and develop the present invention.

### SUMMARY OF THE INVENTION

A main object of the present invention is to provide a method for splitting circles which is mainly applicable to a wafer of semiconductors. A plurality of splitting blades are disposed above the wafer, and conditions and steps are set for switching the plurality of splitting blades based on a safe distance value set at an outer edge of a wafer or a safe distance value set at an inner edge of a metal ring. Accordingly, the plurality of splitting blades are prevented from cutting an outer frame during splitting and failing to complete actions of splitting wafers. The method has an advantage of efficiency of enhancing a production capacity yield rate and enhancing overall practicability.

Another object of the present invention is to provide a method for splitting circles. The plurality of splitting blades for the method is further divided into five length groups. The plurality of splitting blades comprise a first splitting blade, a second splitting blade, a third splitting blade, a fourth splitting blade and a fifth splitting blade according to a length thereof. In a step (b) of the method, a splitting sequence during splitting is set from the fifth splitting blade, the fourth splitting blade, the third splitting blade, the second splitting blade, the first splitting blade, the first splitting blade, the second splitting blade, the third splitting blade, the fourth splitting blade to the fifth splitting blade. The method for splitting circles in accordance with the present invention designs the safe distance values set either at the outer edge of the wafer or the inner edge of the metal ring in order to proceed processes of switching the plurality of splitting blades. As a result, the plurality of splitting blades can be properly changed based on variations in lengths of the wafer or lengths of the inner edge of the metal ring in order to enhance overall safety.

To achieve the above objects, the method for splitting circles of the present invention mainly comprises two embodiments. In the first embodiment, a metal ring is disposed for the method, a circular wafer is disposed within the metal ring. A safe distance value is set at an outer edge of the wafer. A plurality of splitting blades is disposed above the wafer and each of the plurality of splitting blades has a length different from others. A splitting process of the method for splitting circles comprising the following steps: (a) symmetrically arranging the plurality of splitting blades with reference to a center of the wafer based on sizes and lengths thereof; (b) splitting the wafer in sequence from a bottom edge of the wafer to a top edge of the wafer; (c) verifying a difference between the lengths of the plurality of splitting blades and corresponding lengths of the wafer being less than the safe distance value during splitting; and (d) switching the plurality of splitting blades when the difference between the lengths of the plurality of splitting blades and the corresponding lengths of the wafer is more than the safe distance value. In the second embodiment of the method for splitting circles of the present invention, a metal ring is disposed for the method, a circular wafer is disposed within the metal ring. A safe distance value is set at an inner edge of the metal ring. A plurality of splitting blades is disposed above the wafer and each of the plurality of splitting blades has a length different from others. A splitting process of the method for splitting circles comprising the following steps: (a) symmetrically arranging the plurality of splitting blades with reference to a center of the wafer based sizes and lengths thereof; (b) splitting the wafer in sequence from a bottom edge of the wafer to a top edge of the wafer; (c) verifying a difference between lengths of the inner edge of the metal ring and corresponding lengths of the plurality of splitting blades being less than the safe distance value during splitting; and (d) switching the plurality of splitting blades when the difference between the lengths of the inner edge of the metal ring and the corresponding lengths of the plurality of splitting blades is more than the safe distance value.

In order to describe the present invention for better understanding of characteristics, features and technical content thereof, the present invention is explained via the following detailed illustrative embodiments and the attached drawings. However, the attached drawings are only provided for reference and explanation, and are not intended to limit the present invention.

### BRIEF DESCRIPTION OF THE DRAWINGS

FIG. 1 is a planar schematic diagram of a first embodiment of a method for splitting circles in accordance with the present invention.

FIG. 2 is a flow chart of the first embodiment of the method in accordance with the present invention.

FIG. 3 is a planar schematic diagram of a second embodiment of a method for splitting circles in accordance with the present invention.

FIG. 4 is a flow chart of the second embodiment of the method in accordance with the present invention.

### DETAILED DESCRIPTION OF PREFERRED EMBODIMENT

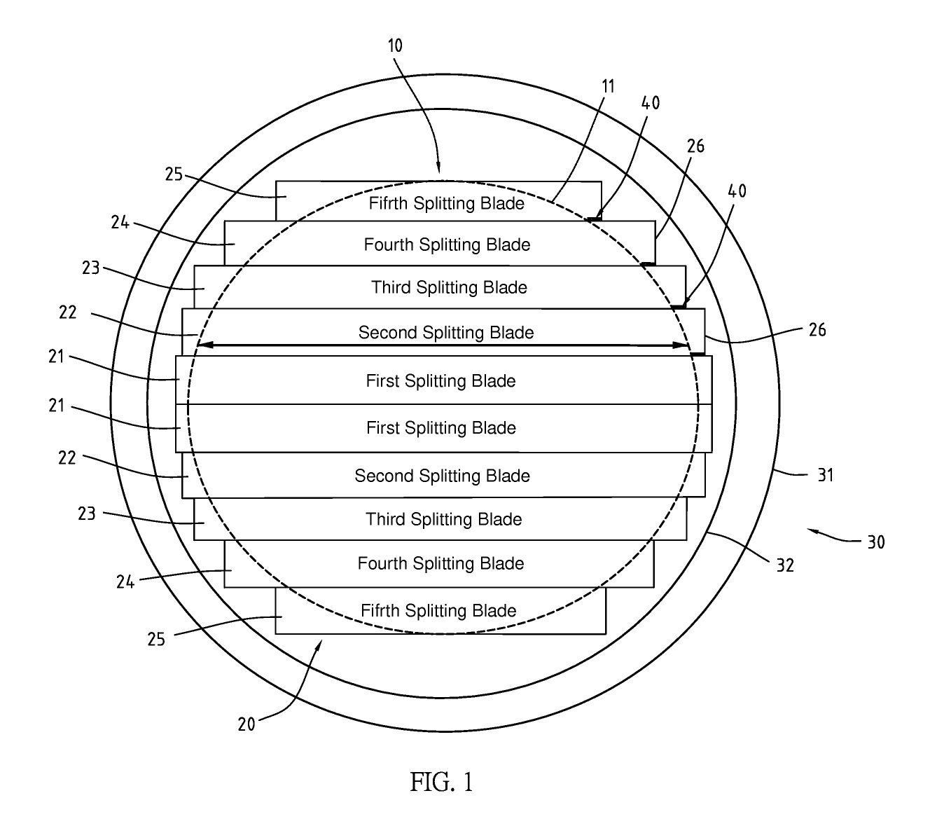

FIGS. 1 to 4 show schematic diagrams for a method for splitting circles in accordance with an embodiment of the present invention. The method for splitting circles in accordance with the present invention is mainly applied to a wafer 10 splitting process. Splitting steps described as the following are able to be adopted to prevent splitting blades 20 from being unable to complete actions of splitting wafers 10 because the splitting blades 20 cut onto an outer frame of a metal ring 30 during splitting. The method has an advantage of enhancing a production capacity yield rate.

The method for splitting circles in accordance with the present invention comprises mainly two embodiments. In a first embodiment of the method for splitting circles in accordance with the present invention, a metal ring 30 is disposed therein, and a wafer 10 is disposed within the metal ring 30. Taking a 12-inch (300 mm) wafer 10 as an example, an outer edge 31 of the metal ring 30 has a diameter of 16 inches (400 mm) and an inner edge 32 thereof has a diameter of 14 inches (350 mm). Hence the wafer 10 is able to be just placed inside the metal ring 30 (as shown in FIG. 1).

Furthermore, a plurality of splitting blades 20 are disposed above the wafer 10. Each of the plurality of splitting blades 20 has a length thereof different from others. In details, the plurality of splitting blades 20 are divided into five length groups. According to lengths thereof, the plurality of splitting blades 20 comprises a first splitting blade 21, a second splitting blade 22, a third splitting blade 23, a fourth splitting blade 24, and a fifth splitting blade 25 disposed therein. The first splitting blade 21 has the longest length and the fifth splitting blade 25 has the shortest length. The plurality of splitting blades 20 are placed equidistantly in sequence from a center of the wafer 10 outwardly. The first splitting blade 21 is placed closest to the center of the wafer 10 while the fifth splitting blade 25 is placed farthest away from the center of the wafer 10, i.e., is placed at a side edge of the wafer 10 (as shown in FIG. 1).

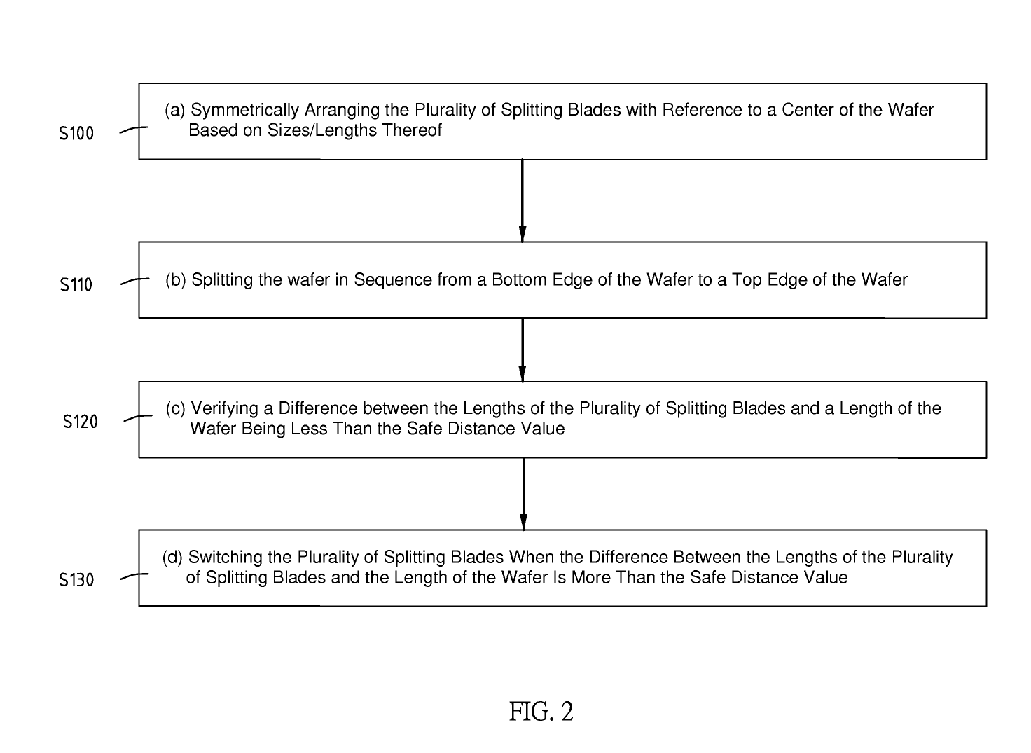

Additionally, in a preferable embodiment of the present invention, a safe distance value 40 is provided at an outer edge 11 of the wafer 10. The safe distance value 40 is a distance from the outer edge 11 of the wafer 10 to a blade edge 26 of the plurality of splitting blades 20. A step S100 or (a) of “symmetrically arranging the plurality of splitting blades 20 with reference to the center of the wafer 10 based on sizes/lengths thereof” of main steps of the splitting process of the method for splitting circles in accordance with the present invention is firstly proceeded. In the step S100, the plurality of splitting blades 20 are firstly symmetrically arranged with reference to the center of the wafer 10 based on sizes/lengths thereof (as shown in FIG. 2). The plurality of splitting blades 20 are able to split the wafer 10 completely during splitting due to the above mentioned arrangement, and as a result, situations of incomplete splitting will not occur. A next step is proceeded after the aforesaid step S100 is completed.

In addition, a step S110 or (b) of “splitting the wafer 10 in sequence from a bottom edge of the wafer 10 to a top edge of the wafer 10” is proceeded next. As shown in FIG. 2, during splitting, the plurality of splitting blades 20 are proceeded to split in sequence from a bottom edge of the wafer 10 to a top edge of the wafer 10. The order of using the plurality of splitting blades 20 is starting from the fifth splitting blade 25, the fourth splitting blade 24, the third splitting blade 23, the second splitting blade 22, the first splitting blade 21, the first splitting blade 21, the second splitting blade 22, the third splitting blade 23, the fourth splitting blade 24 and ending with the fifth splitting blade 25. The plurality of splitting blades 20 are replaceable to match up to lengths of the wafer 10 to be cut. A next step is proceeded after the aforesaid step S110 is finished.

Furthermore, a step S120 or (c) of “verifying a difference between the lengths of the plurality of splitting blades and a length of the wafer 10 being less than the safe distance value” is proceeded next. As shown in FIG. 2, in order to split the wafer 10 completely, a difference between the lengths of plurality of the splitting blades 20 and a length of the wafer 10 during splitting is required to be less than the safe distance value 40. For example, when the length of the wafer 10 is 300 mm, the corresponding length of the plurality of splitting blades 20 is 320 mm and the safe distance value 40 (the distance from the outer edge 11 of the wafer 10 to the blade edge 26 of the plurality of splitting blades 20) is set as 11 mm, The 320 mm length of the plurality of splitting blades 20 minus the 300 mm length of the wafer 10 equals 20 mm, and the 20 mm difference is divided by 2 (two sides of the wafer 10) to equal 10 mm at each of the two sides of the wafer 10, and hence the above result does not exceed the set safe distance value 40 and the purpose of splitting the wafer 10 completely is still achieved. A next step is proceeded after the aforesaid step S120 is finished.

Furthermore, a step S130 or (d) of “switching the plurality of splitting blades 20 when the difference between the lengths of the plurality of splitting blades 20 and the length of the wafer 10 is more than the safe distance value 40” is proceeded next. As shown in FIG. 2, to prevent the plurality of splitting blades 20 from cutting the metal ring 30 during splitting due to the lengths of the plurality of splitting blades 20 being excess, the plurality of splitting blades 20 are switchable when the difference between the lengths of the plurality of splitting blades 20 and the length of the wafer 10 is more than the safe distance value 40 during the splitting process. For example, when a wafer 10 with a length of 300 mm is split and another wafer 10 with a length of 250 mm is about to be split, and the originally used splitting blades 20 with a length of 320 mm is used to proceed splitting, the plurality of splitting blades 20 is too long and easy to cut onto the metal ring 30 so that the splitting action onto the wafer 10 cannot be completed since the 320 mm length of the plurality of splitting blades 20 minus the 250 mm length of the wafer 10 equals 70 mm, the 70 mm difference is divided by 2 (two sides) to equal 35 mm at each of the two sides of the wafer 10, and the result of 35 mm exceeds the set safe distance value 40 (the distance from the outer edge 11 of the wafer 10 to the blade edge 26 of the splitting blades 20) of 11 mm. Therefore, the plurality of splitting blades 20 are switched to have a 270 mm length instead. The 270 mm length of the plurality of splitting blades 20 minus the 250 mm length of the wafer 10 equals 20 mm and the 20 mm difference is divided by 2 (two sides) to equal 10 mm at each of the two sides of the wafer 10. The above result of 10 mm does not exceed the set safe distance value 40. Hence, the purpose of splitting the wafer 10 completely is achieved.

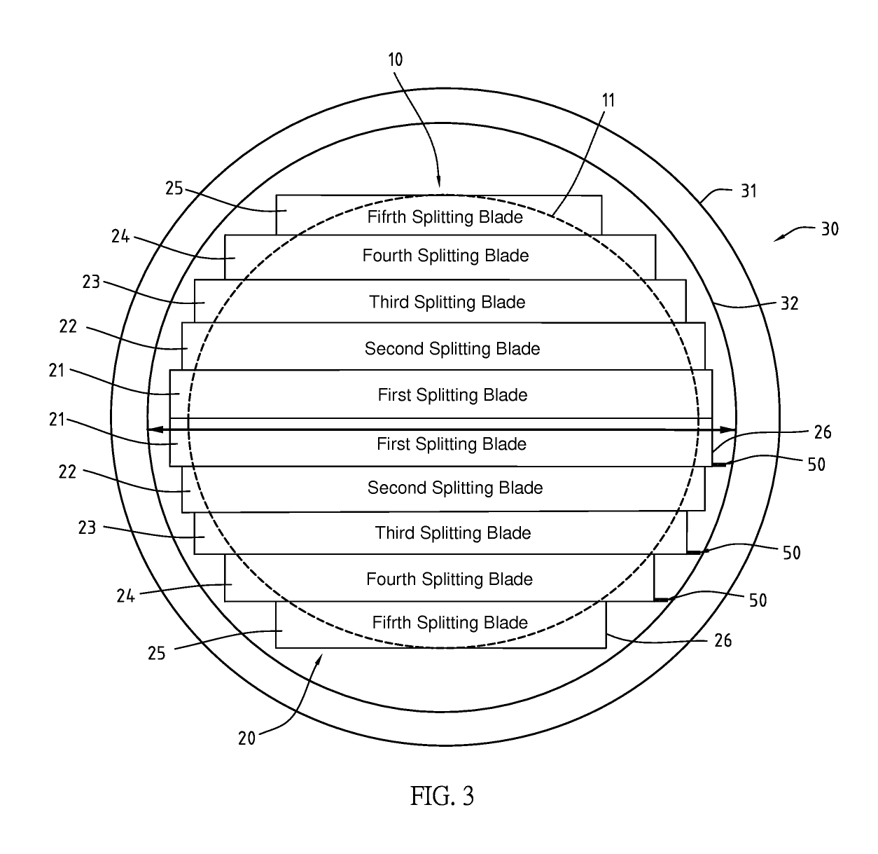

In the second embodiment of the method for splitting circles in accordance with the present invention, a metal ring 30 is disposed therein, and a wafer 10 disposed within the metal ring 30. Taking a 12-inch (300 mm) wafer 10 as an example, an outer edge 31 of the metal ring 30 has a diameter of 16 inches (400 mm) and an inner edge 32 of the metal ring 30 has a diameter of 14 inches (350 mm). Hence, the wafer 10 is able to be just placed inside the metal ring 30 (as shown in FIG. 3).

Furthermore, a plurality of splitting blades 20 are disposed above the wafer 10. Each of the plurality of splitting blades 20 has a length thereof different from others. In details, the plurality of splitting blades 20 are divided into five length groups. According lengths thereof, the plurality of splitting blades 20 comprises a first splitting blade 21, a second splitting blade 22, a third splitting blade 23, a fourth splitting blade 24, and a fifth splitting blade 25 disposed therein. The first splitting blade 21 has the longest length and the fifth splitting blade 25 has the shortest length. The plurality of splitting blades 20 are placed equidistantly in sequence from a center of the wafer 10 outwardly. The first splitting blade 21 is placed closest to the center of the wafer 10 while the fifth splitting blade 25 is placed farthest away from the center of the wafer 10, i.e., is placed at a side edge of the wafer 10 (as shown in FIG. 3).

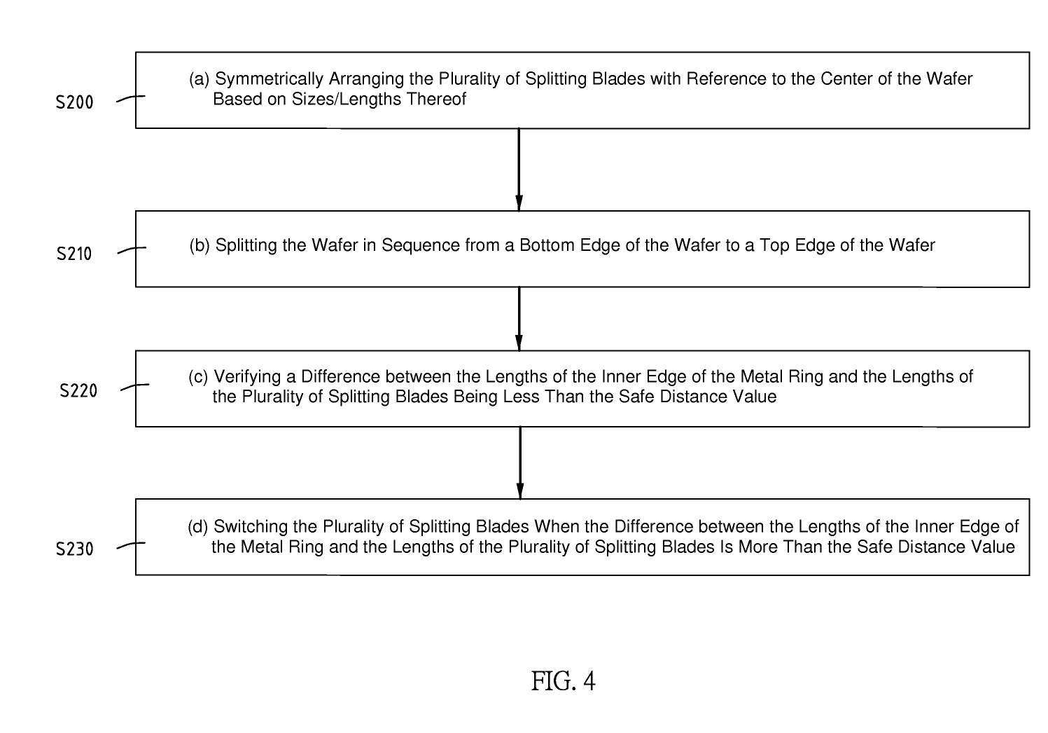

Furthermore, in a preferred embodiment of the present invention, a safe distance value 50 is provided at the inner edge 32 of the metal ring 30. The safe distance value 50 is a distance from the inner edge 32 of the metal ring 30 to the blade edge 26 of the plurality of splitting blades 20. A step of S200 or (a) of “symmetrically arranging the plurality of splitting blades 20 with reference to the center of the wafer 10 based on sizes/lengths thereof” of main steps of the splitting process of the method for splitting circles in accordance with the present invention is firstly proceeded. In the step S200, the plurality of splitting blades 20 are symmetrically arranged with reference to the center of the wafer 10 based on sizes/lengths thereof (as shown in FIG. 4). The plurality of splitting blades 20 are able to split the wafer 10 completely during splitting of the wafer 10 due to the above mentioned arrangement, and as a result, situations of incomplete splitting will not occur. A next step is proceeded after the aforesaid step S200 is finished.

In addition, a step S210 or (b) of “splitting the wafer 10 in sequence from a bottom edge of the wafer 10 to a top edge of the wafer 10” is proceeded next. As shown in FIG. 4, during splitting, the plurality of splitting blades 20 are proceeded to split in sequence from a bottom edge of the wafer 10 to a top edge of the wafer 10. The order of using the plurality of splitting blades 20 is starting from the fifth splitting blade 25, the fourth splitting blade 24, the third splitting blade 23, the second splitting blade 22, the first splitting blade 21, the first splitting blade 21, the second splitting blade 22, the third splitting blade 23, the fourth splitting blade 24 and ending with the fifth splitting blade 25. The plurality of splitting blades 20 are replaceable to match up to lengths of the wafer 10 to be cut. A next step is proceeded after the aforesaid step S210 is finished.

Furthermore, a next step S220 or (c) of “verifying a difference between the lengths of the inner edge 32 of the metal ring 30 and the lengths of the plurality of splitting blades 20 being less than the safe distance value 50” is proceeded next. As shown in FIG. 4, in order to split the wafer 10 completely, a difference between the lengths of the plurality of splitting blades 20 and the lengths of the inner edge 32 of the metal ring 30 during splitting is required to be less than the safe distance value 50. For example, when the length of the wafer 10 is 250 mm, the corresponding length of the inner edge 32 of the metal ring 30 is 280 mm, the corresponding length of the plurality of splitting blades 20 is 270 mm and the safe distance value 50 (the distance from the inner edge 32 of the metal ring 30 to the blade edge 26 of the plurality of splitting blades 20) is set as 11 mm, the 280 mm length of the inner edge 32 of the metal ring 30 minus the 270 mm length of the plurality of splitting blades 20 equals 10 mm, and the 10 mm difference is divided by 2 (two sides of the wafer 10) to equal 5 mm at each of the two sides of the wafer 10, and hence the above result does not exceed the set safe distance value 50 and the purpose of splitting the wafer 10 completely is still achieved. A next step is proceeded after the aforesaid step S220 is finished.

Furthermore, a next step S230 or (d) of “switching the plurality of splitting blades 20 when the difference between the lengths of the inner edge 32 of the metal ring 30 and the lengths of the plurality of splitting blades 20 is more than the safe distance value 50” is proceeded next. As shown in FIG. 4, to prevent the plurality of splitting blades 20 from being unable to split the wafer 10 completely due to short splitting blades 20, the plurality of splitting blades 20 are switchable during splitting when the difference between the lengths of the inner edge 32 of the metal ring 30 and the lengths of the plurality of splitting blades 20 is more than the safe distance value 50. For example, when a wafer 10 with a 250 mm length is split, another wafer 10 with a 300 mm length is about to be split, a length of the inner edge 32 of the metal ring 30 is set as 340 mm, and the originally used splitting blades 20 with a 270 mm length is used to proceed splitting, the plurality of splitting blades 20 is too short and unable to split the wafer 10 completely since the 340 mm length of the inner edge 32 of the metal ring 30 minus the 270 mm length of the originally used plurality of splitting blades 20 equals 70 mm, and the 70 mm difference is divided by 2 (two sides) to equal 35 mm at each of the two sides of the wafer 10, and the result of 35 mm exceeds the set safe distance value 50 (the distance from the inner edge 32 of the metal ring 30 to the blade edge 26 of the splitting blades 20) of 11 mm. Therefore, the plurality of splitting blades 20 are switched to have a 320 mm length instead. The 340 mm length of the inner edge 32 of the metal ring 30 minus the 320 mm length of the plurality of splitting blades 20 equals 20 mm, and the 20 mm difference is divided by 2 (two sides) to equal 10 mm at each of the two sides of the wafer 10. The result of 10 mm does not exceed the set safe distance value 50. Hence the purpose of splitting the wafer 10 completely is achieved.

In this way, the method for splitting circles in accordance with the present invention designs the safe distance values 40, 50 set either at the outer edge 11 of the wafer 10 or the inner edge 32 of the metal ring 30 in order to proceed processes of switching the plurality of splitting blades 20. As a result, the plurality of splitting blades 20 can be properly changed based on variations in lengths of the wafer 10 or lengths of the inner edge 32 of the metal ring 30 in order to enhance overall safety.

As described in details above, any person skilled in this art who is familiar with the present invention can easily understand that the above mentioned objects of the present invention can be indeed achieved by the present invention. The present patent application is hereby filed for a patent to be granted.

Although only the preferred embodiments of the present invention are described as above, the practicing claim scope of the present invention is not limited to the disclosed embodiments. It is understood that any simple equivalent changes, adjustments or modifications to the present invention based on the following claims of the present invention and the content of the above invention description may be still covered within the claimed scope of the following claims of the present invention.

What is claimed is:

1. A method for splitting circles, wherein a metal ring is disposed for the method, a circular wafer is disposed within the metal ring, a safe distance value is set at an outer edge of the wafer, and a plurality of splitting blades are disposed above the wafer, each of the plurality of splitting blades has a length thereof different from others, a main splitting process of the method for splitting circles comprises the following steps:
(a) symmetrically arranging the plurality of splitting blades with reference to a center of the wafer based on sizes and lengths thereof;
(b) splitting the wafer in sequence from a bottom edge of the wafer to a top edge of the wafer;
(c) verifying a difference between the lengths of the plurality of splitting blades and corresponding lengths of the wafer being less than the safe distance value during splitting; and
(d) switching the plurality of splitting blades when the difference between the lengths of the plurality of splitting blades and the corresponding lengths of the wafer is more than the safe distance value.

2. The method for splitting circles as claimed in claim 1, wherein the plurality of splitting blades are further divided into five length groups, and the plurality of splitting blades comprise a first splitting blade, a second splitting blade, a third splitting blade, a fourth splitting blade, and a fifth splitting blade according to a length thereof, and in the step (b), a splitting sequence during splitting is set from the fifth splitting blade, the fourth splitting blade, the third splitting blade, the second splitting blade, the first splitting blade, the first splitting blade, the second splitting blade, the third splitting blade, the fourth splitting blade to the fifth splitting blade.

3. The method for splitting circles as claimed in claim 1, wherein the safe distance value set at the outer edge of the wafer is further set as a distance from the outer edge of the wafer to a blade edge of the plurality of splitting blades.

4. A method for splitting circles, wherein a metal ring is disposed for the method, a circular wafer is disposed within the metal ring, a safe distance value is set at an inner edge of the metal ring, and a plurality of splitting blades are disposed above the wafer, each of the plurality of splitting blades has a length thereof different from others, a main splitting process of the method for splitting circles comprises the following steps:
(a) symmetrically arranging the plurality of splitting blades with reference to a center of the wafer based sizes and lengths thereof;
(b) splitting the wafer in sequence from a bottom edge of the wafer to a top edge of the wafer;
(c) verifying a difference between lengths of the inner edge of the metal ring and corresponding lengths of the plurality of splitting blades being less than the safe distance value during splitting; and
(d) switching the plurality of splitting blades when the difference between the lengths of the inner edge of the metal ring and the corresponding lengths of the plurality of splitting blades is more than the safe distance value.

5. The method for splitting circles as claimed in claim 4, wherein the plurality of splitting blades are further divided into five length groups, and the plurality of splitting blades comprise a first splitting blade, a second splitting blade, a third splitting blade, a fourth splitting blade, and a fifth splitting blade according to a length thereof, and in the step (b), a splitting sequence during splitting is set from the fifth splitting blade, the fourth splitting blade, the third splitting blade, the second splitting blade, the first splitting blade, the first splitting blade, the second splitting blade, the third splitting blade, the fourth splitting blade to the fifth splitting blade.

6. The method for splitting circles as claimed in claim 4, wherein the safe distance value set at the inner edge of the metal ring is further set as a distance from the inner edge of the metal ring to a blade edge of the plurality of splitting blades.
